(19) United States
(12) Patent Application Publication
(10) Pub. No.: US 2016/0268286 A1
(43) Pub. Date: Sep. 15, 2016

(54) METHOD OF MANUFACTURING SEMICONDUCTOR DEVICE AND SEMICONDUCTOR DEVICE

(71) Applicant: Kabushiki Kaisha Toshiba, Minato-ku (JP)

(72) Inventor: Shinpei TAMURA, Yokkaichi (JP)

(73) Assignee: Kabushiki Kaisha Toshiba, Minato-ku (JP)

(21) Appl. No.: 14/729,209

(22) Filed: Jun. 3, 2015

Related U.S. Application Data
(60) Provisional application No. 62/131,546, filed on Mar. 11, 2015.

(51) Int. Cl. H01L 27/115

(52) U.S. Cl. CPC H01L 27/11575; H01L 27/1157; H01L 27/11582

(57) ABSTRACT

According to one embodiment of a method of manufacturing a semiconductor device, a film stack in which a first film and a second film are alternately and repeatedly stacked is formed on a semiconductor substrate. Further, silicon oxide which is a first interlayer insulation film is formed at a non-stack area where the film stack is not disposed up to a predetermined height. Furthermore, a silicon compound film including at least one of nitride, carbon, and boron is embedded as a second interlayer insulation film in a recessed portion inside the non-stack area. Additionally, dry etching processing is simultaneously applied to the film stack, and the first and second interlayer insulation films by using a fluorocarbon-based gas.

### CROSS-REFERENCE TO RELATED APPLICATIONS

This application is based upon and claims the benefit of priority from U.S. Provisional Application No. 62/131,546, filed on Mar. 11, 2015; the entire contents of which are incorporated herein by reference.

### FIELD

Embodiments described herein relate generally to a method of manufacturing a semiconductor device and a semiconductor device.

### BACKGROUND

There is a three-dimensional device as one of the semiconductor devices, in which a plurality of memory cell patterns is stacked. In such a three-dimensional device, an interlayer insulation film and a film stack to be the memory cell pattern are simultaneously processed in order to reduce the number of manufacturing steps.

However, in the case of simultaneously processing the film stack and the interlayer insulation film, a processed shape may become different depending on a processing position due to a difference of a material structure between the film stack and the interlayer insulation film. Therefore, in the case of manufacturing the three-dimensional device, it is demanded that the three-dimensional device is processed in a desired processed shape.

### BRIEF DESCRIPTION OF THE DRAWINGS

FIG. 1 is a top view illustrating a memory cell area and a stepped area according to a first embodiment;

FIGS. 2A to 2E are diagrams for describing a slit forming processing procedure according to the first embodiment;

FIG. 3 is a diagram illustrating a forming area of a silicon oxynitride film according to the first embodiment;

FIGS. 4A to 4C are diagrams illustrating cross-sectional shapes of the slit according to the first embodiment;

FIGS. 5A to 5C are diagrams for describing the slit forming processing procedure in the case where the silicon oxynitride film is not disposed on an interlayer insulation film;

FIG. 6 is a diagram illustrating the cross-sectional shape of the slit in the case where the silicon oxynitride film is not disposed on the interlayer insulation film;

FIG. 7 is a diagram illustrating a cross-sectional structure of a semiconductor device according to the first embodiment;

FIG. 8 is a diagram illustrating a structure of a silicon oxynitride film according to a second embodiment;

FIG. 9 is a diagram illustrating a cross-sectional structure of a semiconductor device according to the second embodiment;

FIGS. 10A and 10B are diagrams for describing a reason why a bowing shape is prevented by disposing the silicon oxynitride film; and

FIG. 11 is a diagram for describing a reason why the bowing shape is formed in the case where the silicon oxynitride film is not disposed on the interlayer insulation film.

### DETAILED DESCRIPTION

In general, according to one embodiment, a method of manufacturing a semiconductor device is provided. In the method of manufacturing a semiconductor device, a film stack in which a first film and a second film are alternately and repeatedly stacked is formed on a semiconductor substrate. Further, silicon oxide which is a first interlayer insulation film is formed at a non-stack area where the film stack is not disposed up to a predetermined height. Additionally, a recessed portion is provided in an area having a thickness of the silicon oxide larger than a predetermined value within the non-stack area. Further, a silicon compound film including at least one element out of nitrogen, carbon, and boron is embedded in the recessed portion as a second interlayer insulation film. Further, dry etching processing is simultaneously applied to the film stack, and the first and second interlayer insulation films by using a fluorocarbon-based gas. Then, a groove pattern to segment the film stack, and the first and second interlayer insulation films is formed.

Exemplary embodiments of the method of manufacturing a semiconductor device and the semiconductor device will be described below in detail with reference to the accompanying drawings. The present invention is not limited to the following embodiments.

### First Embodiment

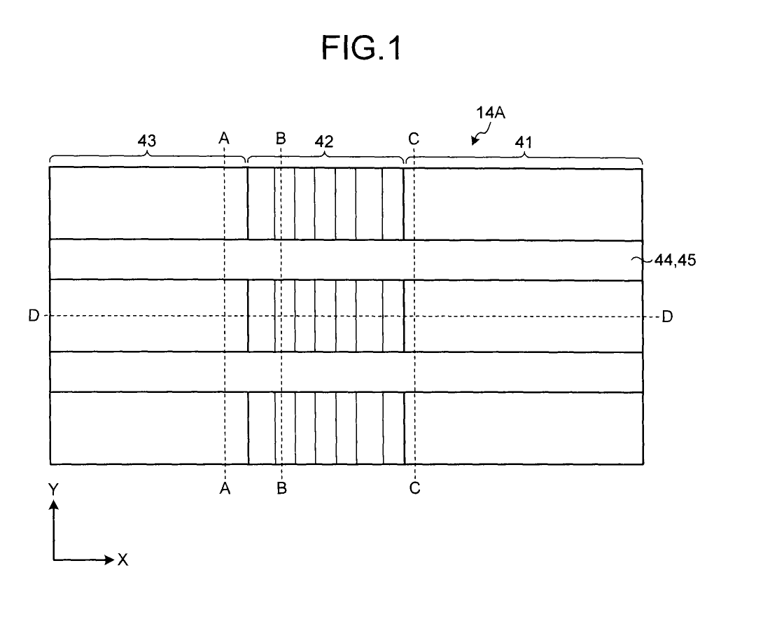

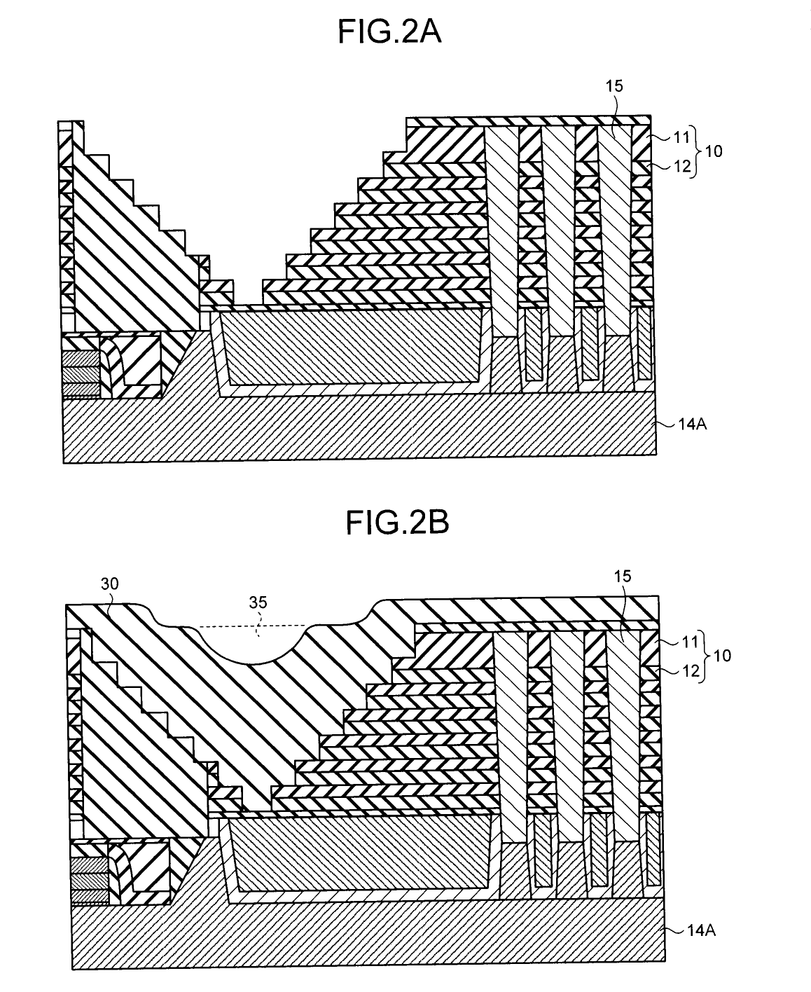

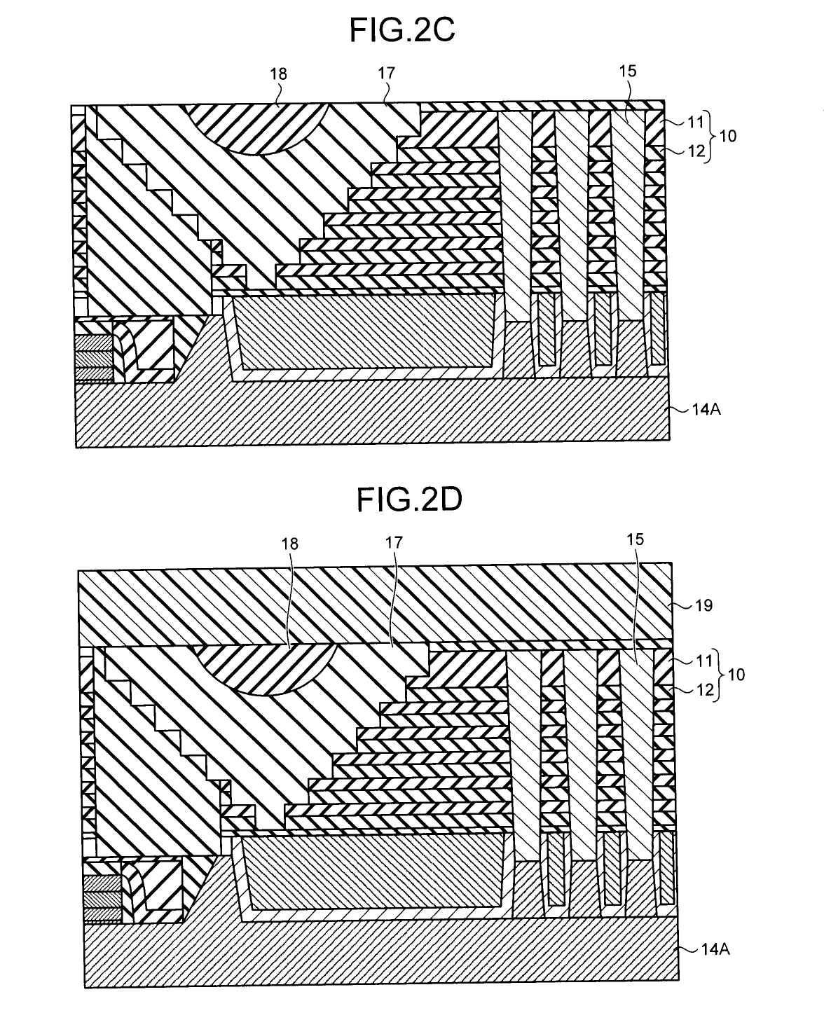

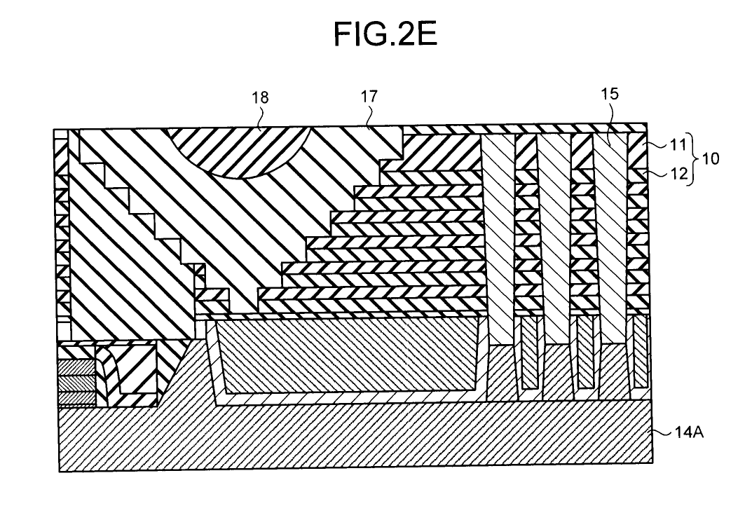

FIG. 1 is a top view illustrating a memory cell area and a stepped area according to a first embodiment. FIGS. 2A to 2E are diagrams for describing a slit forming processing procedure according to the first embodiment. In the present embodiment, a method of manufacturing a semiconductor device (three-dimensional device) in which a plurality of memory cell patterns is stacked will be described.

In FIG. 1, illustration of an interlayer insulation film and the like is omitted. FIGS. 2A to 2E are diagrams illustrating cross-sectional views of a substrate (semiconductor substrate) 14A such as a wafer. Further, FIGS. 2A to 2E are the cross-sectional views of the semiconductor device in FIG. 1 taken along a line D-D.

The semiconductor device (three-dimensional device) having memory cell patterns of a stacking structure includes a memory cell pattern in which a plurality of memory layers is stacked. The memory cell patterns are formed at a memory cell area 41 on a substrate 14A illustrated in FIG. 1. Further, a stepped area 42 and a peripheral area 43 are provided on the substrate 14A as non-stack areas which are the areas other than memory cell area 41.

One end portion in a longitudinal direction (X-direction) of the memory cell area 41 is the stepped area 42. In the stepped area 42, layers same as the memory layers are stacked stepwise. Meanwhile, in FIGS. 2A to 2E, illustrated is a previous structure (stacked insulation layers 10) before the film stack in the memory cell area 41 and stepped area 42 become a stacked structure including an electrode layer (tungsten layer, etc.) and the memory layer.

One end portion in the X-direction of the stepped area 42 is connected to the memory cell area 41. Further, the other end portion in the X-direction of the stepped area 42 is adjacent to the peripheral area 43. The memory cell area 41 is segmented by a slit 44 which is a groove pattern. Further, the slit 44 segments the stepped area 42. Furthermore, the slit 44 segments the peripheral area 43. The slit 44 is, for example, the groove pattern having a value of an aspect ratio larger than 25. A conductive film and an insulation film are embedded in the slit 44, thereby forming an isolating portion 45.

When the memory cell pattern is formed, a plurality of insulation layers 10 including silicon oxide 11/silicon nitride 12 (SiO/SiN) is stacked on the substrate 14A as illustrated in FIG. 2A. This forms a multi-layer pattern in which SiO and SiN are alternately repeated. The silicon nitride 12 inside the insulation layers 10 is a layer to be an interconnection layer in subsequent processing.

After the insulation layers 10 are stacked, a resist pattern is formed on a more upper layer side than the insulation layers 10. Further, etching for a layer of the insulation layers 10 by reactive ion etching (RIE) and slimming for the resist pattern are repeated. By this, the stepwise pattern is sequentially formed layer-by-layer from an upper layer portion side relative to a stacked body of the insulation layers 10 formed of the plurality of layers.

After completion of etching for the lowest layer of the insulation layer 10, a film of silicon oxide (interlayer insulation film 30) such as tetraethyl orthosilicate (TEOS) is formed on the substrate 14A as illustrated in FIG. 2B. The interlayer insulation film 30 is formed by using chemical vapor deposition (CVD), for example. The interlayer insulation film 30 includes unevenness (steps) corresponding to unevenness (steps) on the substrate 14A.

More specifically, since a cross-sectional structure in the vicinity of a boundary between the stepped area 42 and the peripheral area 43 is formed in a recessed shape, a cross-sectional structure of the interlayer insulation film 30 on an upper portion side of the recessed shape also becomes a recessed shape (recessed portion 35). In other words, the recessed portion 35 has a depth corresponding to a height of a step on the substrate 14A at each position of the peripheral area 43 and stepped area 42.

A center (bottom portion) in the case of viewing the recessed portion 35 from above is located on a deepest portion of the patterns (steps) formed on the substrate 14A. More specifically, a deepest bottom portion of the recessed portion 35 is located on the boundary between the stepped area 42 and the peripheral area 43. Thus, the area where the recessed portion 35 is formed is an area where no insulation layer 10 is formed and further a film thickness of the interlayer insulation film 30 is smaller than a predetermined value.

The depth of the deepest portion of the recessed portion 35 (distance from a bottom surface of a later-described mask pattern 19 to a bottom surface of the recessed portion 35) is, for example, deeper than 300 nm. The recessed portion 35 is deep in a place where the film thickness of the interlayer insulation film 30 is thick, and is shallow in a place where the film thickness of the interlayer insulation film 30 is thin. In other words, the recessed portion 35 has the depth corresponding to the film thickness of the interlayer insulation film 30.

In the case of viewing the substrate 14A from the top, the recessed portion 35 is shaped circular or oval, and further the cross-sectional shape is formed like a bowl. The recessed portion 35 has a shape corresponding to a shape of a step on the substrate 14A at each position of the peripheral area 43 and the stepped area 42. Note that a size of the recessed portion 35 (upper surface size, bottom surface size, depth, etc.) may be a size corresponding to etching power at the time of forming the slit 44.

After the interlayer insulation film 30 including the recessed portion 35 is formed, a silicon oxynitride film (SiON) is formed on a more upper layer side than the interlayer insulation film 30. In other words, a silicon oxynitride film (embedding portion) 18 is embedded in the recessed portion 35 (upper side of the interlayer insulation film 30). A silicon oxynitride film 18 is formed to the depth of, for example, 400 nm or so. The silicon oxynitride film 18 is formed by using CVD, for example.

Further, the silicon oxynitride film 18 and the interlayer insulation film 30 are etched back by chemical mechanical polishing (CMP) or the like. By this, the interlayer insulation film 30 becomes an interlayer insulation film 17 and the silicon oxynitride film 18 both flattened as illustrated in FIG. 2C. The interlayer insulation film 17 herein is silicon oxide (TEOS) same as the interlayer insulation film 30. Since the silicon oxynitride film 18 is embedded in the recessed portion 35, the silicon oxynitride film 18 has a thickness corresponding to a height of a step on the substrate 14A at each position of the peripheral area 43 and the stepped area 42. In other words, the silicon oxynitride film 18 has the thickness corresponding to the film thickness of the interlayer insulation film 17 at each position of the peripheral area 43 and the stepped area 42.

After the interlayer insulation film 17 and the silicon oxynitride film 18 are flattened, the mask pattern 19 is formed as illustrated in FIG. 2D. The mask pattern 19 is used to form the slit 44. The mask pattern 19 is, for example, a CVD carbon mask pattern including a groove pattern of 140 nm. The mask pattern 19 is formed by, for example, dry etching with oxygen plasma.

The substrate 14A is etched from above the mask pattern 19 by using discharge plasma or the like, thereby forming the slit 44 on the substrate 14A. More specifically, the slit 44 is formed by applying plasma dry etching with a fluorocarbon gas to a lower layer side of the mask pattern 19.

The slit 44 is formed in an area to segment the memory cell area 41, an area to segment the stepped area 42, and an area to segment the peripheral area 43. Therefore, the insulation layer 10 formed of the plurality of layers, and the interlayer films (interlayer insulation film 17 and silicon oxynitride film 18) are simultaneously etched. Note that the interlayer insulation film 17 and the silicon oxynitride film 18 may be referred to as the interlayer films in the following.

In the case of using the dry etching processing to process the slit 44, the processing can be accelerated by activating (ionizing) a processing gas. Further, the activated processing gas adheres to a side wall surface applied with etching, and protects the side wall surface. Therefore, since side etching is suppressed at the time of processing the slit 44, anisotropic vertical processing can be executed.

After the slit 44 is formed, the mask pattern 19 is peeled off from above the substrate 14A as illustrated in FIG. 2E. The mask pattern 19 is peeled off from above the substrate 14A by ashing with oxygen plasma, for example. Note that the slit 44 is not illustrated in FIGS. 2D and 2E because FIGS. 2D and 2E are cross-sectional views of the semiconductor device in FIG. 1 taken along the line D-D.

The slit 44 at a position to segment the memory cell area 41 has a width of, for example, 160 nm. Further, the slit 44 of the deepest portion at a position to segment the stepped area 42 has a width of, for example, 210 nm.

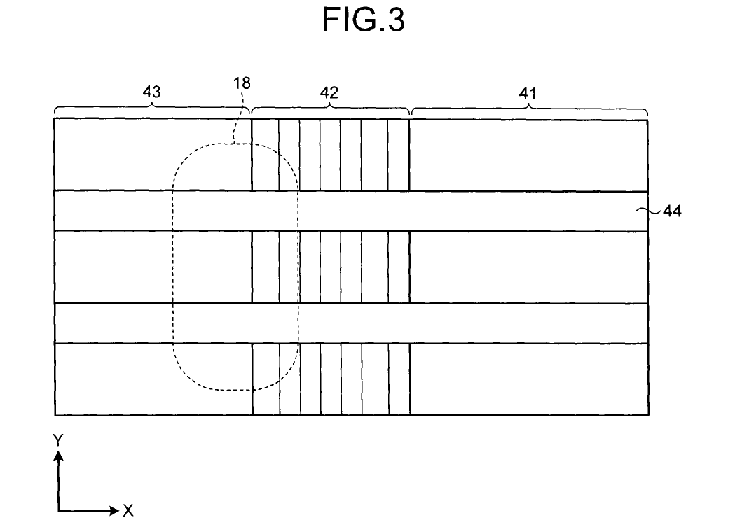

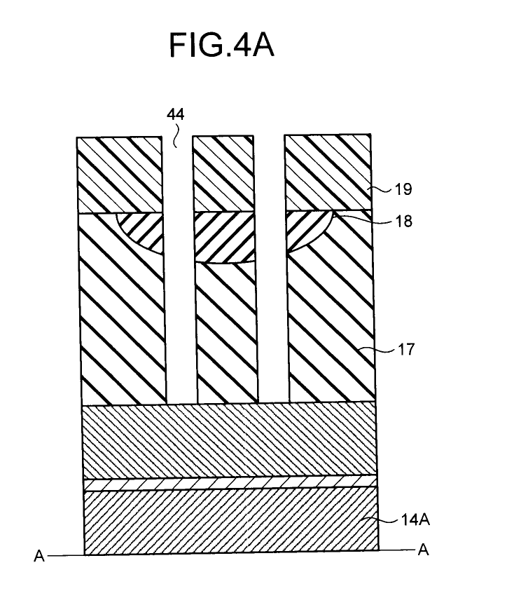

Now, a shape of the silicon oxynitride film 18 embedded in the recessed portion 35 will be described. FIG. 3 is a diagram illustrating a forming area of the silicon oxynitride film according to the first embodiment. FIG. 3 is a diagram illustrating a top view of the silicon oxynitride film 18. On the substrate 14A, the silicon oxynitride film 18 is disposed on an area including an area where the slit 44 is formed and the peripheral area 43.

The interlayer insulation film 30 has the recessed portion 35 on the upper side of a bottom (area of lower steps) of the steps. More specifically, the boundary between the stepped area 42 and the peripheral area 43 is the bottom of the steps. Therefore, the boundary between the stepped area 42 and the peripheral area 43 is to be a center of the recessed portion 35 (bottom portion of the bowl shape). Therefore, the center of the silicon oxynitride film 18 embedded in the recessed portion 35 is to be the boundary between the stepped area 42 and the peripheral area 43. Thus, the silicon oxynitride film 18 is embedded in a place where the film thickness of the interlayer insulation film 30 is larger than the predetermined value.

In the slit 44 which is the groove pattern, the larger influence of SiO, namely, the interlayer insulation film 17 is given while being etched (groove processing) in a place where the thickness of the interlayer insulation film 17 is thicker. Further, in the case where the influence of SiO is large, a cross-sectional shape of the slit 44 does not become a desired shape.

According to the present embodiment, the silicon oxynitride film 18 is formed at a place where the thickness of the interlayer insulation film 17 is thicker than a predetermined value (boundary between the stepped area 42 and the peripheral area 43). Therefore, according to the present embodiment, the slit 44 is influenced by the silicon oxynitride film 18 while being etched.

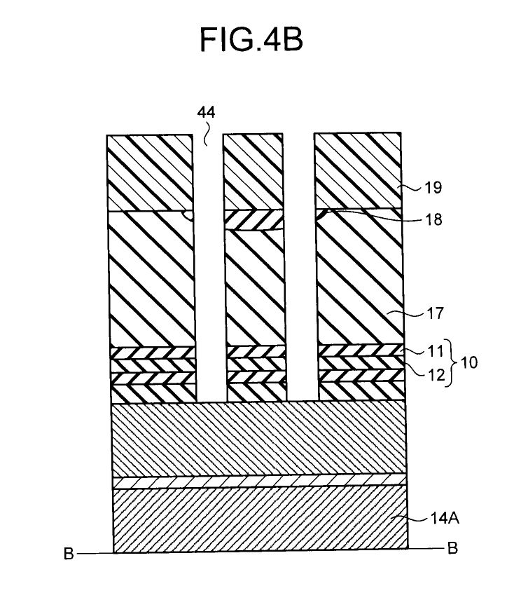

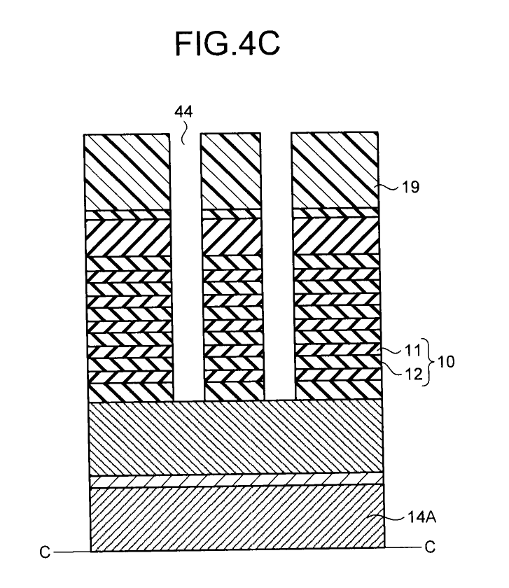

Next, the shape of the slit 44 will be described. FIGS. 4A to 4C are diagrams illustrating cross-sectional shapes of the slit according to the first embodiment. In FIGS. 4A to 4C, the cross-sectional shapes of the slit 44 after the mask pattern 19 is peeled off from above the substrate 14A are illustrated. FIG. 4A is the cross-sectional view of the substrate 14A in FIG. 1 taken along an A-A line inside the peripheral area 43. Further, FIG. 4B is the cross-sectional view of the substrate 14A in FIG. 1 taken along a B-B line inside the stepped area 42. Additionally, FIG. 4C is the cross-sectional view of the substrate 14A in FIG. 1 taken along a C-C line inside the memory cell area 41.

As illustrated in FIG. 4A, the interlayer films are segmented by the slit 44 in the peripheral area 43. Further, inside the peripheral area 43, the film thicknesses of the interlayer films are thick in the vicinity of the boundary between the stepped area 42 and the peripheral area 43. According to the present embodiment, the silicon oxynitride film 18 is disposed on the vicinity of the boundary. Therefore, the slit 44 is influenced by the silicon oxynitride film 18 and the interlayer insulation film 17 while being etched. As a result, the slit 44 inside the peripheral area 43 comes to have a linear cross-sectional shape from the upper layer portion to the lower layer portion.

As illustrated in FIG. 4B, the interlayer films and the insulation layer 10 are segmented by the slit 44 inside the stepped area 42. Further, the thicknesses of the interlayer films are medium in the stepped area 42. According to the present embodiment, the silicon oxynitride film 18 is disposed on the stepped area 42. Therefore, the slit 44 is influenced by the silicon oxynitride film 18, interlayer insulation film 17, and insulation layer 10 while being etched. As a result, the slit 44 inside the stepped area 42 has the linear cross-sectional shape from the upper layer portion to the lower layer portion.

Note that, inside the stepped area 42, the silicon oxynitride film 18 is not necessarily disposed in an area where the thicknesses of the interlayer films are thin. In this case, the interlayer insulation film 17 and the insulation layer 10 are segmented by the slit 44 inside the stepped area 42.

Further, as illustrated in FIG. 4C, there is no interlayer film in the memory cell area 41. Therefore, the slit 44 is not influenced by the interlayer film while being etched. As a result, the slit 44 inside the memory cell area 41 has the linear cross-sectional shape from the upper layer portion to the lower layer portion.

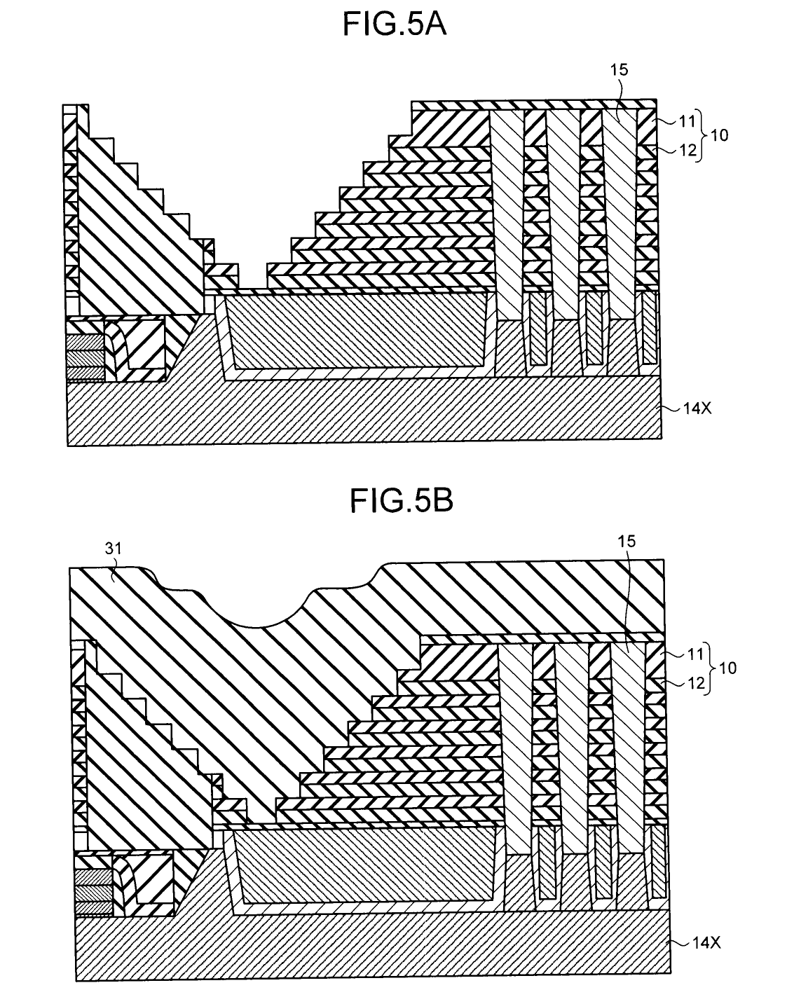

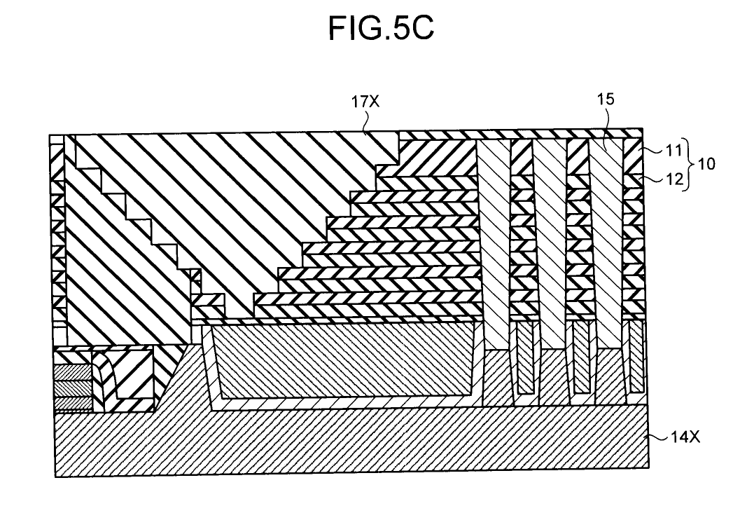

Now, slit processing in the case where the silicon oxynitride film 18 is not disposed on the interlayer insulation film 17 will be described. FIGS. 5A to 5E are diagrams for describing a slit forming procedure in the case where the silicon oxynitride film is not disposed on the interlayer insulation film.

As illustrated in FIG. 5A, a plurality of insulation layers 10 including the silicon oxide 11/silicon nitride 12 is stacked on the substrate 14X. After that, the resist pattern is formed on the more upper layer side than the insulation layers 10. Further, etching for one insulation layer 10 by the RIE, and sliming for the resist pattern are repeated. By this, the stepwise pattern is sequentially formed layer-by-layer from the upper layer portion side relative to the stacked body of the insulation layers 10 formed of the plurality of layers.

After completion of etching for the lowest layer of the insulation layer 10, an interlayer insulation film 31 such as TEOS is formed on the substrate 14X as illustrated in FIG. 5B. The interlayer insulation film 31 is formed slightly thicker than the interlayer insulation film 30. A cross-sectional structure of the interlayer insulation film 31 has a recessed shape on the upper portion side same as the interlayer insulation film 30.

After the interlayer insulation film 31 is formed, the interlayer insulation film 31 is etched back by the CMP or the like. By this, the interlayer insulation film 31 is formed as a flattened interlayer insulation film 17X as illustrated in FIG. 5C.

After that, when the substrate 14X is etched from above the mask pattern, the slit (slit 44X described later) is formed on the substrate 14X. While this etching, influence of SiO, namely, the interlayer insulation film 17X is largely given. Further, in the case where the influence of SiO is large, the cross-sectional shape of the slit 44X does not become a desired shape.

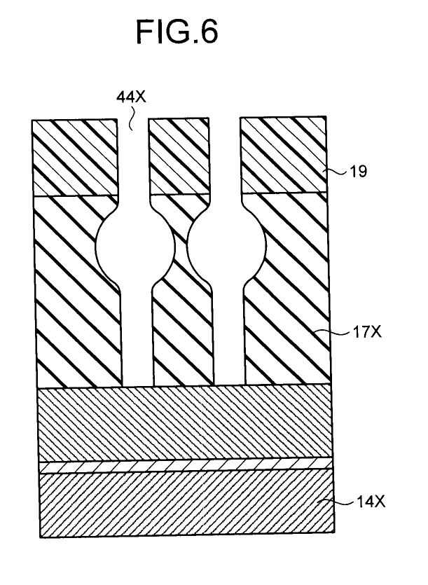

Now, a shape of the slit 44X will be described. FIG. 6 is a diagram illustrating the cross-sectional shape of the slit in the case where the silicon oxynitride film is not disposed on the interlayer insulation film. The interlayer films are thick in the vicinity of the boundary between the stepped area 42 and the peripheral area 43, and the like. Therefore, the slit 44X is influenced by the interlayer insulation film 17X while being etched. As a result, the cross-sectional shape of the slit 44X does not become a desired shape.

More specifically, an upper portion side (opening portion side) of the slit 44X is etched more than a desired amount because of the influence from the interlayer insulation film 17X. Therefore, the upper portion side of the slit 44X has a groove pattern size larger than a lower portion side of the slit 44X. As a result, the slit 44X has a shape in which the upper portion side bulges out than the lower portion side (bowing shape). In the case where the slit 44X comes to have the bowing shape, the slit 44X may interfere with a hole formed at the interlayer insulation film 17X and the insulation layer 10.

As for the substrate 14A of the present embodiment, a conductive film and an insulation film are embedded in the slit 44 after the slit 44 is formed. By this, the slit 44 is formed as the isolating portion 45. Further, for the substrate 14A, an electrode layer and a memory cell layer are formed. By this, the semiconductor device including the memory cell pattern is formed. Now, a cross-sectional structure of the semiconductor device according to the first embodiment will be described.

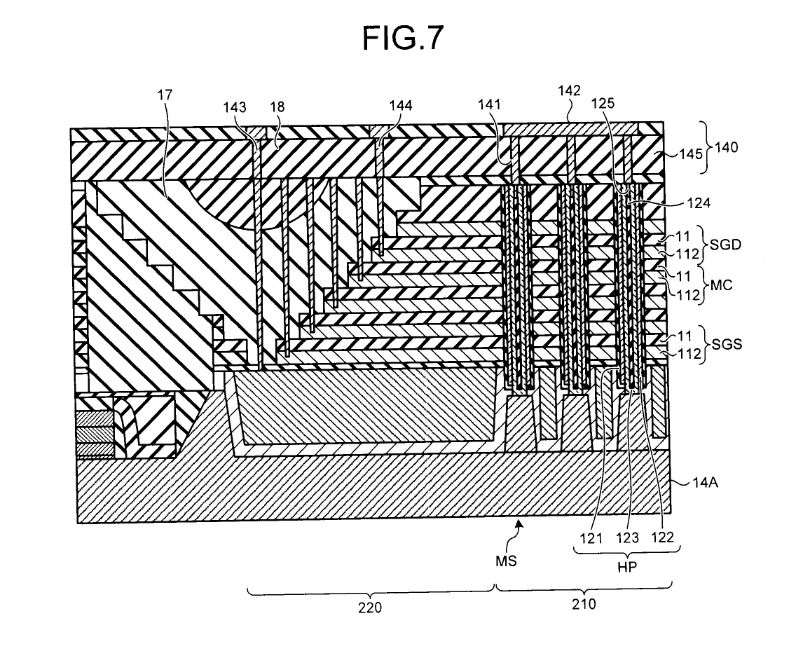

FIG. 7 is a diagram illustrating the cross-sectional structure of the semiconductor device according to the first embodiment. FIG. 7 schematically illustrates an example of the cross-sectional structure in a direction perpendicular to a bit line direction at a memory cell portion 210 and a word line contact portion 220 in the semiconductor device (non-volatile semiconductor storage device) according the present embodiment. The memory cell portion 210 is formed at the memory cell area 41, and the word line contact portion 220 is formed at the stepped area 42.

In the memory cell portion 210, a memory string MS is almost vertically and two-dimensionally disposed on the substrate 14A as illustrated in FIG. 7. The memory string MS has a structure in which a plurality of transistors is connected in series. The memory string MS includes a pillar portion HP and an electrode film 112. The electrode film 112 is formed of a metal film, such as tungsten, at a position from where the silicon nitride 12 is removed.

The pillar portion HP has a structure in which an ONO films 121 that form a hollow columnar tunnel insulation film, a charge storage film, and an inter-electrode insulation film are stacked on outer peripheral surfaces of hollow columnar semiconductor films 123, 122. The hollow columnar semiconductor films 123, 122 are channels of the transistors that form the memory string MS. For the semiconductor films 123, 122, a polysilicon film obtained by annealing amorphous silicon can be used, for example. The electrode films 112 are disposed at a plurality of places in a height direction of the pillar portion HP via the silicon oxide 11. The silicon oxide 11 here functions as a spacer film.

Meanwhile, an embedding insulation film 124 such as a silicon oxide film is embedded inside the hollow columnar semiconductor film 123 up to a predetermined height, and a cap film 125 such as a P-type amorphous silicon film is embedded in a portion higher than the predetermined height.

In an array of the transistors connected in series in the height direction, the transistors located at both upper and lower ends are selection transistors SGS, SGD. In the example of FIG. 7, a source-side selection transistor SGS is disposed on the lower side, and a drain-side selection transistor SGD is disposed on the upper side. One or more memory cell transistors MC are formed at predetermined intervals between the two selection transistors SGS and SGD. In this example, structures of the selection transistors SGS, SGD are same as a structure of the memory cell transistor MC.

The memory cell portion 210 and the word line contact portion 220 are segmented by the isolating portion 45 extending in a word line direction. The isolating portion 45 has a structure in which the conductive film and the insulation film such as the silicon oxide film are embedded in the slit 44 that penetrates the stacked body in a thickness direction. In the stacked body, the electrode film 112 and the silicon oxide 11 which is the spacer film are stacked.

The transistors having the same height in an area interposed between the isolating portions 45 are connected by the same electrode film 112. For example, the source-side selection transistor SGS in the area interposed between the isolating portions 45 are connected by the electrode film 112 at the lowest layer. The drain-side selection transistor SGD in the area interposed between the isolating portions 45 are connected by the electrode film 112 at the uppermost layer. These electrode films 112 are to be selection gate lines.

Further, the memory cell transistors MC having the same height in the area interposed between the isolating portions 45 are connected by the respective electrode films 112. The electrode film 112 connecting the memory cell transistors MC is to be a word line.

The electrode films 112 extended from the memory cell portion 210 are disposed in the word line contact portion 220 in a stacked manner. The electrode films 112 are formed in a stepped structure so as to expose the electrode films 112 at lower layers. The word line contact portion 220 also has the structure in which the silicon oxide 11 is disposed between the electrode films 112 vertically adjacent.

Thus, in the memory cell portion 210 and the word line contact portion 220, the silicon oxide 11 which is the insulation film, and the electrode film 112 which is the conductive film are alternately and repeatedly stacked. The interlayer insulation film 17 and the silicon oxynitride film 18 are provided on the electrode films 112 formed stepwise at the word line contact portion 220.

An interconnection forming layer 140 is formed on the memory string MS of the memory cell portion 210 and on the interlayer insulation film 17 and silicon oxynitride film 18 of the word line contact portion 220. The interconnection forming layer 140 has a structure in which a patterned interconnection layer 141 is disposed between interlayer insulation films 145 stacked in the height direction.

A contact 141 connecting an upper end of the memory string MS with the interconnection layer 142 is disposed at the interlayer insulation film 145. Further, a contact 144 is provided at the interlayer insulation film 145, interlayer insulation film 17, and silicon oxynitride film 18 so as to connect the interconnection layer 142 with the electrode film 112 in each of the steps in the word line contact portion 220.

Moreover, a peripheral circuit and the like are disposed at the substrate 14A besides the above. In the peripheral circuit, an element such as a transistor not illustrated is disposed. The transistor of the peripheral circuit (source area) is connected to a contact 143.

Meanwhile, in the present embodiment, the case where the slit 44 is formed after a contact hole 15 is formed inside the memory cell area 41 has been described but the slit 44 may be formed before the contact hole 15 is formed. Further, the slit 44 may be formed after the film stack in the memory cell area 41 and the stepped area 42 has become the stacking structure formed of the electrode layers and the memory layers.

Also, instead of the silicon oxynitride film 18, a silicon nitride film (SiN) may be embedded in the recessed portion 35. Additionally, instead of the silicon oxynitride film 18, the silicon compound film including at least one of nitrogen (N), carbon (C), and boron (B) may be embedded in the recessed portion 35. In this case, oxygen (O) may be included in the silicon compound film. Examples of the interlayer insulation film to be embedded in the recessed portion 35 are SiN, SiON, SiC, and SiBN.

Thus, according to the first embodiment, the insulation layer 10 in which the silicon oxide 11 and the silicon nitride 12 are alternately stacked, and the interlayer insulation film 17 formed in the area different from the insulation layer 10 are simultaneously processed. Further, in the substrate 14A, the silicon oxynitride film 18 is embedded on the upper layer side (recessed portion 35) of the interlayer insulation film 17. Moreover, dry etching processing is applied to the interlayer insulation film 17 from above the silicon oxynitride film 18 with the fluorocarbon-based gas. By this, nitrogen is supplied from the silicon oxynitride film 18 when the slit 44 is formed at the interlayer insulation film 17. Therefore, the slit 44 is prevented from having a bowing shape. Therefore, in the case of manufacturing the three-dimensional device, the three-dimensional device can be processed in a desired processed shape.

### Second Embodiment

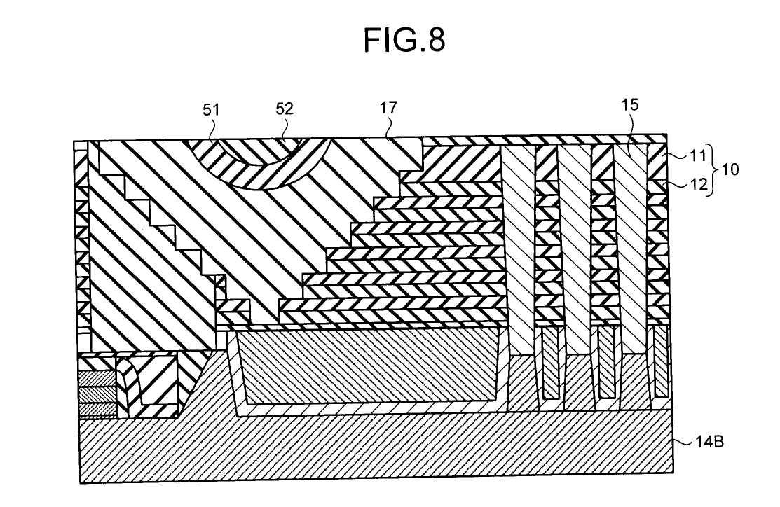

Next, a second embodiment of the present invention will be described by using FIGS. 8 to 11. According to the second embodiment, a silicon oxynitride film is disposed at a recessed portion 35 up to a predetermined depth, and further TEOS is disposed at an upper portion of the silicon oxynitride film.

FIG. 8 is a diagram illustrating a structure of the silicon oxynitride film according to the second embodiment. In FIG. 8, a cross-sectional view of a substrate 14B such as a wafer is illustrated. Among respective components in FIG. 8, the same components as the substrate 14A in a first embodiment illustrated in FIG. 2C are denoted by the same reference signs, and repetition of the description therefor will be omitted.

According to the present embodiment, a silicon oxynitride film 51 is embedded up to the predetermined depth from a bottom surface of the recessed portion 35. Further, in the recessed portion 35, an interlayer insulation film 52 is embedded more on an upper layer side than the silicon oxynitride film 51. The silicon oxynitride film 51 is formed by using CVD, for example. Further, the interlayer insulation film 52 is formed by using CVD, for example.

The silicon oxynitride film 51 has a shape (bowl-like shape) same as a lower portion of a silicon oxynitride film 18. Further, the interlayer insulation film 52 has a shape same as an upper portion of the silicon oxynitride film 18. Further, a portion combining the silicon oxynitride film 51 and the interlayer insulation film 52 has a shape same as the silicon oxynitride film 18.

In the case where the silicon oxynitride film 18 is not disposed, the silicon oxynitride film 51 is disposed at a position inside the slit 44 where a bowing shape is formed. According to the present embodiment, the silicon oxynitride film 51 is disposed from the bottom surface up to a predetermined height (e.g., thickness 100 nm) in the recessed portion 35. Further, the interlayer insulation film 52 is disposed on the upper portion side in the recessed portion 35 where an effect of preventing the bowing shape is little. The silicon oxynitride film 51 is a film formed of a member same as the silicon oxynitride film 18. The interlayer insulation film 52 is a film formed of a member same as an interlayer insulation film 17.

A depth in a deepest portion of the recessed portion 35 is deeper than 300 nm, for example. Further, a portion of the interlayer insulation film 52 having a thickest film thickness is thinner than 200 nm, for example. Additionally, a portion of the silicon oxynitride film 51 having a thickest film thickness is thicker than 100 nm, for example.

When the silicon oxynitride film 51 and the interlayer insulation film 52 are formed, the silicon oxynitride film 51 and the interlayer insulation film 52 are flattened in the same method as the first embodiment after being stacked. Note that the silicon oxynitride film 51 may be formed to have a thickness corresponding to a height of a step on the substrate 14B at each position of a peripheral area 43 and a stepped area 42.

Etching for the slit 44 is applied to the substrate 14B where the silicon oxynitride film 51 and the interlayer insulation film 52 are disposed, and the slit 44 prevented from having the bowing shape can be formed same as the first embodiment.

The slit 44 at a position to segment a memory cell area 41 has a width of, for example, 160 nm. Further, the slit 44 of a deepest portion at a position to segment the stepped area 42 has a width of, for example, 220 nm.

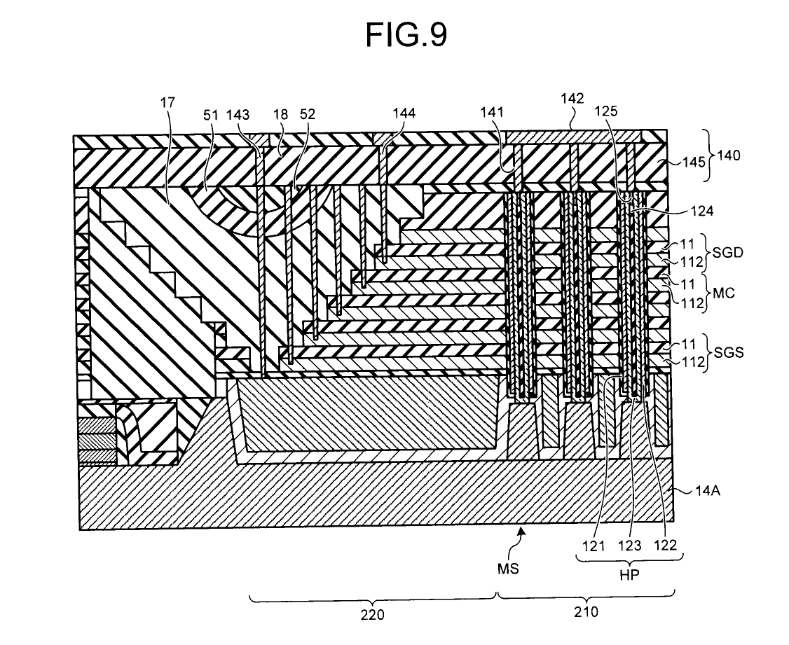

FIG. 9 is a diagram illustrating a cross-sectional structure of a semiconductor device according to the second embodiment; In FIG. 9, schematically illustrated is an example of the cross-sectional structure in a direction perpendicular to a bit line direction at a memory cell portion 210 and a word line contact portion 220 in the semiconductor device (non-volatile semiconductor storage device) according the present embodiment. Among respective components in FIG. 9, the same components as the substrate 14A in the first embodiment illustrated in FIG. 7 are denoted by the same reference signs, and repetition of the description therefor will be omitted.

The semiconductor device of the present embodiment includes the memory cell portion 210 and the word line contact portion 220 same as the semiconductor device of the first embodiment. In the semiconductor device according to the present embodiment, the silicon oxynitride film 51 and the interlayer insulation film 52 are disposed instead of the silicon oxynitride film 18.

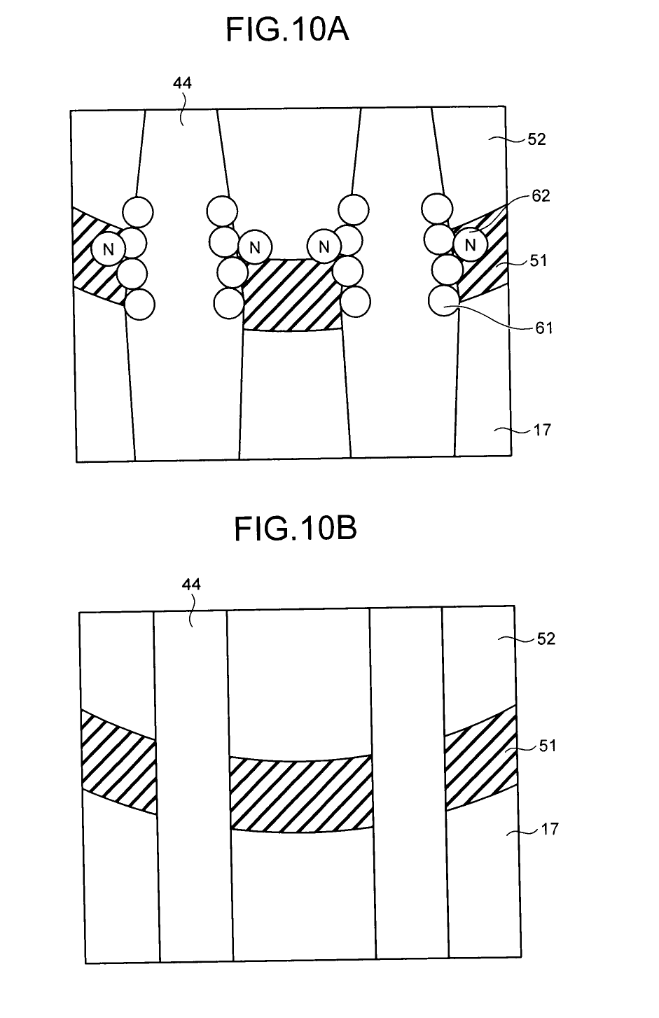

Next, the reason why the bowing shape is prevented by disposing the silicon oxynitride films 18, 51 will be described. FIGS. 10A and 10B are diagrams for describing the reason why the bowing shape is prevented by disposing the silicon oxynitride film. Note that in the case of disposing the silicon oxynitride film 18, the bowing shape is prevented by the same principle as the case of disposing the silicon oxynitride film 51. Therefore, the reason why the bowing shape is prevented by disposing the silicon oxynitride film 51 will be described here.

As illustrated in FIG. 10A, the silicon oxynitride film 51 includes nitride (N) 62, and includes oxygen less than the interlayer insulation film 17. Therefore, when the slit 44 is etched, an amount of oxygen generated from the silicon oxynitride film 51 is only less than the interlayer insulation film 17.

When the slit 44 is etched, fluorocarbon-based (CF-based) side wall sediment (sediment 61) supplied from plasma are generated. The sediment 61 is a protective component for the side wall. Further, oxygen generated from oxidation products generated during etching easily reacts with the sediment 61. Therefore, the sediment 61 tends to remain inside the slit 44 when only a small amount of oxygen is generated during etching. Further, when a large amount of sediment 61 remains inside the slit 44, side etching for a side wall surface hardly progresses in the slit 44.

Thus, in the case where the silicon oxynitride film 51 is disposed at the recessed portion 35, the sediment 61 inside the slit 44 is more increased than the case where only the interlayer insulation film 17 is disposed. Therefore, by disposing the silicon oxynitride film 51 at the recessed portion 35, the bowing shape is prevented. As a result, as illustrated in FIG. 10B, the shape of the slit 44 becomes a substantially column shape in which the bowing shape is prevented.

As described above, the disposed silicon oxynitride film 51 supplies, to the CF-based gas, less oxygen which easily reacts with carbon, compared to a silicon oxide layer. Therefore, in the case of using the silicon oxynitride film 51, the sediment 61 adhering to the side wall (inner wall surface) of the slit 44 is more increased than the case of using only the interlayer insulation film 17 which is silicon oxide. As a result, protective performance for the side wall by the fluorocarbon-based gas becomes more enhanced. Therefore, the upper portion side of the slit 44 can be prevented from forming the bowing shape.

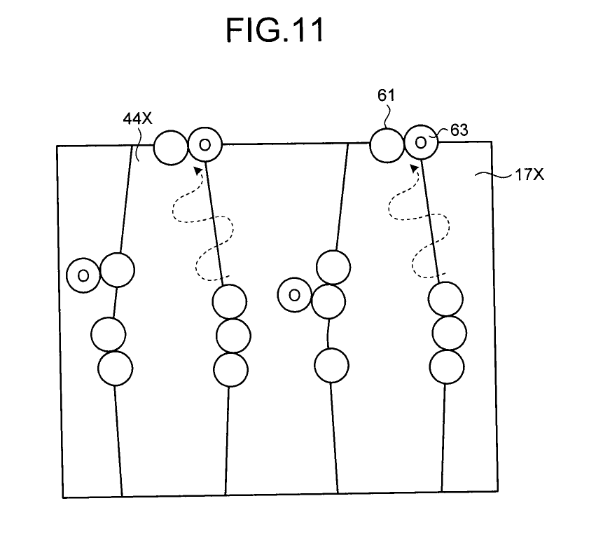

FIG. 11 is a diagram for describing a reason why the bowing shape is formed in the case where the silicon oxynitride film is not disposed on the interlayer insulation film. An interlayer insulation film 17X includes more oxygen (O) 63 than the silicon oxynitride film 51. Therefore, when a slit 44X is etched, a larger amount of oxygen 63 is generated from the interlayer insulation film 17X than the silicon oxynitride film 51.

When the slit 44X is etched, CF-based sediment 61 which is the protective component for the side wall are generated. Further, the oxygen 63 generated during etching easily reacts with the sediment 61. Therefore, when a large amount of the oxygen 63 is generated during etching, the sediment 61 hardly remains inside the slit 44X. Further, when only a small amount of the sediment 61 remains inside the slit 44X, protective performance for the side wall surface becomes weak in the slit 44X, and side etching tends to progress.

Thus, in the case where only the interlayer insulation film 17X is disposed at the recessed portion 35, the amount of the sediment 61 inside the slit 44X is more reduced than the case where the silicon oxynitride film 51 is disposed. Therefore, the bowing shape is easily formed by disposing only the interlayer insulation film 17X at the recessed portion 35. As a result, the shape of the slit 44 comes to have the bowing shape as illustrated in FIG. 11.

Meanwhile, instead of the silicon oxynitride film 51 or the interlayer insulation film 52, a silicon compound film including at least one of nitrogen (N), carbon (C), and boron (B) may be embedded. In this case, oxygen (O) may be included in the silicon compound film. Examples of the silicon compound film or the interlayer insulation film 52 are SiN, SiON, SiC, and SiBN.

Thus, according to the second embodiment, an insulation layer 10 in which silicon oxide 11 and silicon nitride 12 are alternately stacked, and the interlayer insulation film 17 formed in the area different from the insulation layer 10 are simultaneously processed. Further, in the substrate 14B, the silicon oxynitride film 51 and the interlayer insulation film 52 are embedded on the upper layer side (recessed portion 35) of the interlayer insulation film 17. Furthermore, dry etching processing is applied to the interlayer insulation film 17 from above the silicon oxynitride film 51 and the interlayer insulation film 52 with a fluorocarbon-based gas. By this, nitride is supplied from the silicon oxynitride film 51 when the slit 44 is formed at the interlayer insulation film 17. Therefore, the slit 44 can be prevented from having the bowing shape. Therefore, in the case of manufacturing the three-dimensional device, the three-dimensional device can be processed in a desired processed shape.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, comprising:
forming, on a semiconductor substrate, a film stack where a first film and a second film are alternately and repeatedly stacked;
forming silicon oxide, which is a first interlayer insulation film, on a non-stack area where the film stack is not disposed up to a predetermined height;
providing a recessed portion in an area having a film thickness of the silicon oxide larger than a predetermined value within the non-stack area;
embedding, in the recessed portion, a silicon compound film including at least one of nitride, carbon, and boron as a second interlayer insulation film;
simultaneously applying dry etching processing to the film stack and the first and second interlayer insulation films by using a fluorocarbon-based gas; and
forming a groove pattern to segment the film stack, and the first and second interlayer insulation films.

2. The method of manufacturing a semiconductor device according to claim 1, wherein
the silicon compound film has a thickness corresponding to a film thickness of the silicon oxide at each position inside the non-stack area.

3. The method of manufacturing a semiconductor device according to claim 1, wherein
the recessed portion has a depth corresponding to a height of a step on the semiconductor substrate at each position inside the non-stack area.

4. The method of manufacturing a semiconductor device according to claim 1, wherein
the dry etching processing is executed after flattening the first and second interlayer insulation films.

5. The method of manufacturing a semiconductor device according to claim 1, wherein
a third interlayer insulation film is stacked on an upper side of the silicon compound film, and the third interlayer insulation film is embedded on an upper side of the recessed portion.

6. The method of manufacturing a semiconductor device according to claim 5, wherein
the dry etching processing is executed after flattening the first to third interlayer insulation films.

7. The method of manufacturing a semiconductor device according to claim 1, wherein
the first film is a SiO film, and
the second film is a SiN film.

8. The method of manufacturing a semiconductor device according to claim 1, wherein
the silicon compound film is a SiN film, a SiON film, a SiC film, or a SiBN film.

9. The method of manufacturing a semiconductor device according to claim 5, wherein
the third interlayer insulation film is a SiO film, a SiN film, a SiON film, a SiC film, or a SiBN film.

10. The method of manufacturing a semiconductor device according to claim 1, wherein
the recessed portion has a depth deeper than 300 nm.

11. A semiconductor device comprising:
a film stack where memory cells are three-dimensionally disposed on a semiconductor substrate;
silicon oxide, which is a first interlayer insulation film formed in a non-stack area where the film stack is not disposed up to a predetermined height;
a silicon compound film as a second interlayer insulation film configured to be embedded in a recessed portion provided in an area having a film thickness of the silicon oxide larger than a predetermined value within the non-stack area, and further the silicon compound film including at least one of nitride, carbon, and boron; and
an isolating portion configured to segment the film stack, and the first and second interlayer insulation films.

12. The semiconductor device according to claim 11, wherein
the silicon compound film has a thickness corresponding to a film thickness of the silicon oxide at each position inside the non-stack area.

13. The semiconductor device according to claim 11, wherein
the recessed portion has a depth corresponding to a height of a step on the semiconductor substrate at each position inside the non-stack area.

14. The semiconductor device according to claim 11, wherein
the first and second interlayer insulation films are flattened.

15. The semiconductor device according to claim 11, further comprising
a third interlayer insulation film stacked on an upper side of the silicon compound film, wherein
the third interlayer insulation film is embedded on an upper side of the recessed portion.

16. The semiconductor device according to claim 15, wherein
the first to third interlayer insulation films are flattened.

17. The semiconductor device according to claim 11, wherein
the film stack is a film in which an insulation film and a conductive film are alternately and repeatedly stacked.

18. The semiconductor device according to claim 11, wherein
the silicon compound film is a SiN film, a SiON film, a SiC film, or a SiBN film.

19. The semiconductor device according to claim 15, wherein
the third interlayer insulation film is a SiO film, a SiN film, a SiON film, a SiC film, or a SiBN film.

20. The semiconductor device according to claim 11, wherein
the recessed portion has a depth deeper than 300 nm.
